(19) United States
(12) Patent Application Publication
(10) Pub. No.: US 2015/0109721 A1
(43) Pub. Date: Apr. 23, 2015

(54) CORD-MOUNTED REMOTE CONTROL DEVICE

(71) Applicant: Lutron Electronics Co., Inc., Coopersburg, PA (US)

(72) Inventors: Mark E. Willcocks, Sellersville, PA (US); Louis G. Rollo, Hellertown, PA (US); Brian R. O'Donnell, Alburtis, PA (US)

(73) Assignee: Lutron Electronics Co., Inc., Coopersburg, PA (US)

(21) Appl. No.: 14/057,482

(22) Filed: Oct. 18, 2013

(51) Int. Cl. H05K 7/00

(52) U.S. Cl. CPC H05K 7/00
USPC 361/679.01; 248/65

(57) ABSTRACT

A remote control assembly may include a housing to which a remote control device may be attached (e.g., releasably attached). The remote control assembly may be configured to mount to a cord, for example an electrical cord that includes an insulating sheath. The housing of the remote control assembly may define a path therethrough that is configured to receive a portion of the electrical cord. The housing may be configured to restrain the cord such that the housing remains in a mounted location on the cord. For example, the housing may be configured to engage the insulating sheath of the electrical cord at one or more locations along the path through the housing. The remote control assembly may include a remote control device that is configured to control a load control device, for example via wireless communication signals transmitted from the remote control device.

### BACKGROUND

A load control system may be used to control an amount of power delivered to an associated electrical load, for example to dim a lighting load that is electrically connected to the load control system. A load control system may include, for example, a dimmer switch that is electrically connected to the lighting load and that is configured to dim the lighting load by controlling the amount of power delivered to the lighting load.

The dimmer switch of such a load control system, for example a wallbox dimmer switch, may be configured to be controlled via wireless signals, such as radio-frequency (RF) signals, received from a remote control device that is associated with the load control system.

The remote control device of a load control system may be configured such that it can be at least temporarily attached to a mount, such as a cradle, in a known location. For example, a remote control device may be configured to attach to a mount that is integrated with a wallbox dimmer switch, or to a mount that is attached directly to the surface of a wall. Examples of such remote control device mounting configurations are described in more detail in commonly-assigned U.S. Pat. No. 8,389,857, issued Mar. 5, 2013, entitled “Structure for Mounting a Wireless Battery-Powered Remote Control,” the entire disclosure of which is incorporated herein by reference.

FIG. 1 illustrates a prior art lighting control system 100 that is deployed in a bedroom. The lighting control system 100 includes a table lamp 120, a plurality of recessed lights 130, and one or more load control devices (not shown), such as dimmer switches, that are electrically connected to the table lamp 120 and the recessed lights 130. The lighting control system 100 includes a remote control device 140 that is configured to control the one or more load control devices using wireless communication, for example via RF signals 150. By controlling the amount of power delivered via the one or more load control devices, the remote control device 140 is capable of controlling the table lamp 120 and the recessed lights 130 (e.g., by setting respective dimming levels). The lighting control system 100 includes a mount 142 for the remote control device 140. The mount 142 is attached to a wall of the bedroom, in a location remote from the table lamp 130 and the recessed lights 120. The remote control device 140 may be operated to control the recessed lights 120 and/or the table lamp 130 both when it is attached to the mount 142 and when it is removed from the mount 142 and remains within RF signal range of the one or more dimmer switches. An example remote control device that may be implemented as the remote control device 140 is described in more detail in commonly-assigned U.S. Pat. No. 8,330,638, issued Dec. 11, 2012, entitled “Wireless Battery-Powered Remote Control Having Multiple Mounting Means,” the entire disclosure of which is incorporated herein by reference.

However, deploying the remote control device 140 and the mount 142, for example as depicted in FIG. 1, may hinder use of the lighting control system 100 in certain usage scenarios. For example, in an example usage scenario, the remote control device 140 may be lost or misplaced, for example if a user forgets to return it to its mount 142. In an alternative configuration, the lighting control system 100 may include a pedestal mount (not shown) for the remote control device 140 (e.g., in addition to or in place of the mount 142). The pedestal mount may be configured to be disposed on a flat surface, such as a bedside table. In such a configuration, the remote control device 140 may be lost or misplaced, for example if the pedestal mount breaks or falls off the bedside table while the remote control device 140 is mounted to it. In another example usage scenario, a user of the lighting control system 100 may inadvertently forget to retrieve the remote control device 140 from the mount 142, for example before getting into bed, and thus may be inconvenienced by having to get up to retrieve it from its mount in order to control the lighting in the bedroom.

### SUMMARY

As disclosed herein, a remote control assembly may include a housing to which a remote control device may be attached, for example releasably attached. The remote control assembly may be configured to mount to a cord, for example an electrical cord that includes an insulating sheath.

Such a remote control assembly may be configured to be mounted to a cord at a location desirable for use of the remote control device. Such a use location may be near an associated device that may be controlled by the remote control device. For example, the remote control assembly may be configured to mount to the electrical cord of a lamp that the remote control device is configured to control.

The housing of the remote control assembly may define a path therethrough that is configured to receive a portion of the electrical cord. The housing may be configured to restrain the cord such that the housing remains in a mounted location on the cord. For example, the housing may be configured to engage the insulating sheath of the electrical cord at one or more locations along the path through the housing.

The remote control assembly may include a remote control device that is configured to control a load control device, for example via wireless communication signals transmitted from the remote control device. The housing of the remote control assembly may be configured such that the remote control device may be releasably attached to the housing. The remote control assembly may be configured such that the remote control device may be fixedly mounted to the housing, so as to discourage misplacement or theft of the remote control device. For example, the housing may include an attachment component that is configured to captively engage a portion of the remote control device.

### BRIEF DESCRIPTION OF THE DRAWINGS

FIG. 1 is a simplified diagram of an example prior art lighting control system that includes one or more dimmer switches, various lighting loads, and a remote control device that is configured to control the lighting loads via the one or more dimmer switches.

FIG. 2 is a simplified diagram of an example lighting control system that includes one or more dimmer switches, various lighting loads, and a cord-mounted remote control assembly that is configured to control the lighting loads via the one or more dimmer switches.

FIG. 3A is a front-facing perspective view of an example cord-mounted remote control assembly.

FIG. 3B is a rear-facing perspective view of the example cord-mounted remote control assembly depicted in FIG. 3A.

FIG. 3C is a front elevation view of the example cord-mounted remote control assembly depicted in FIG. 3A.

FIG. 3D is a side elevation view of the example cord-mounted remote control assembly depicted in FIG. 3A.

FIG. 3E is an end elevation view of the example cord-mounted remote control assembly depicted in FIG. 3A.

FIG. 4A is an exploded view of an example cord-mounted remote control assembly that includes a two piece housing and a remote control device.

FIG. 4B is a perspective view of the example cord-mounted remote control assembly of FIG. 4A, with the housing mounted to an electrical power cord, and with the remote control device separated from the housing.

FIG. 5A is a perspective view of the cover portion of the housing of the example cord-mounted remote control assembly of FIG. 4A.

FIG. 5B is a front elevation view of the cover portion depicted in FIG. 5A.

FIG. 6 is a front elevation view of the cover portion depicted in FIG. 5A, after an electrical power cord has been disposed in a path through the cover portion.

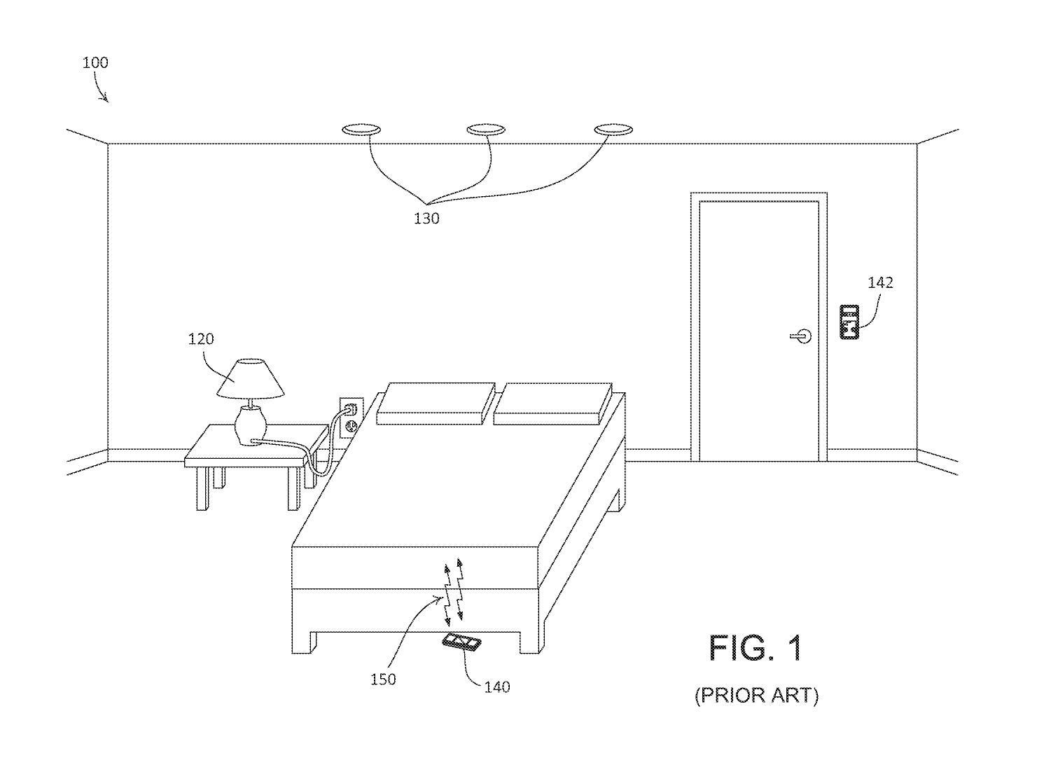

### DETAILED DESCRIPTION

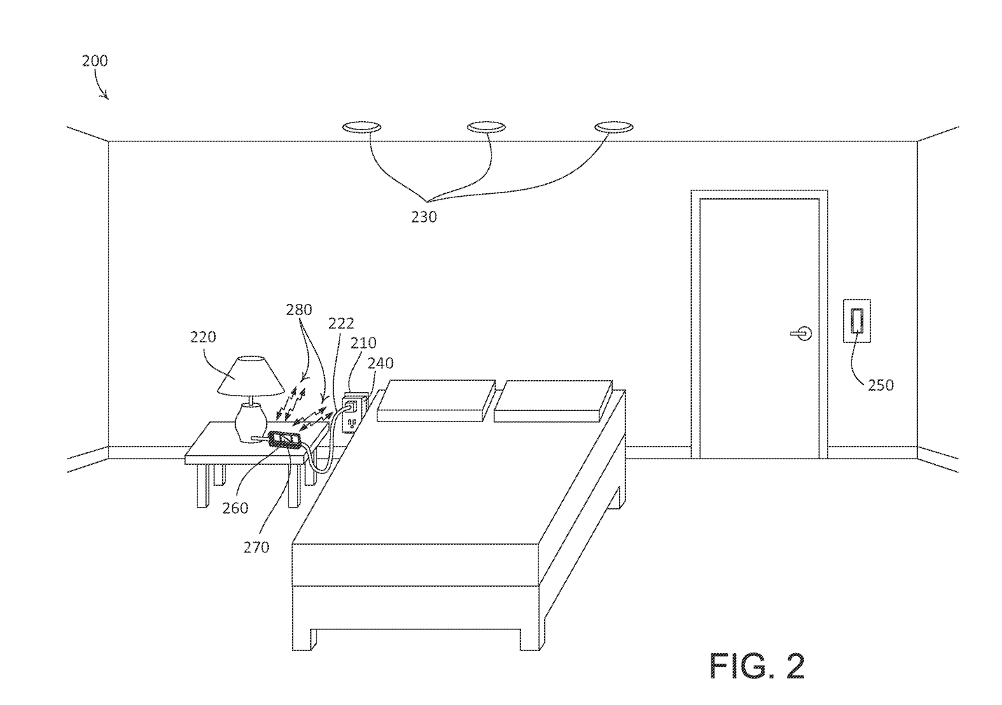

FIG. 2 illustrates an example load control system. As shown, the load control system is a lighting control system 200. The lighting control system 200 includes a table lamp 220 and a plurality of recessed lights 230. The lighting control system 200 includes a first load control device 240 that is electrically connected to the table lamp 220 and that is configured to control an amount of power that is delivered to the table lamp 220. As shown, the first load control device 240 is a plug-in radio-frequency (RF) dimmer switch that is plugged into a receptacle 210 that is coupled to a source of alternating current (AC) power. The table lamp 220 is electrically connected to the first load control device 240 via the power cord 222 of the table lamp 220 that is plugged into the first load control device 240. The lighting control system 200 includes a second load control device 250 that is electrically connected to the recessed lights 230 and that is configured to control an amount of power that is delivered to the recessed lights 230. As shown, the second load control device 250 is an RF dimmer switch that is configured to be wall-mounted in a standard electrical wallbox.

The lighting control system 200 includes a cord-mounted remote control assembly 260 that may be fixedly mounted to a portion of the power cord 222 of the table lamp 220. For example, the cord-mounted remote control assembly 260 may be configured such that when mounted to the power cord 222 at a selected location, the cord-mounted remote control assembly 260 will resist being moved from the selected location. Securely mounting the remote control assembly 260, for example to the power cord 222, may be desirable. For example, such a mounting configuration may maintain the cord-mounted remote control assembly 260 in a known location (e.g., relative to the table lamp 220 that it controls), and may secure the remote control assembly 260 so as to deter misplacement or theft of the remote control assembly 260. The power cord 222 may be, for example, standard 18/2 lamp wire.

As shown, the cord-mounted remote control assembly 260 includes a remote control device 270. The remote control device 270 may be configured to communicate wirelessly, for example via RF signals 280, with one or both of the first and second load control devices 240, 250. Using such wireless communications, the remote control device 270 may control the table lamp 220 and/or the recessed lights 230. For example, operating one or more controls of the remote control device 270 may cause the remote control device 270 to transmit RF signals 280 to one or both of the first and second load control devices 240, 250 via. Such signals may be indicative of commands to be executed by one or both of the first and second load control devices 240, 250. Such commands may, for example, cause one or both of the first and second load control devices 240, 250 to adjust respective amounts of power delivered to the table lamp 220 and/or the recessed lights 230 (e.g., to set respective dimming levels of the table lamp 220 and/or the recessed lights 230).

The lighting control system 200 is illustrative of an example load control system in which the cord-mounted remote control assembly 260 may be deployed. It should be appreciated that the cord-mounted remote control assembly 260 may alternatively be deployed in other suitable load control system configurations. For example, the cord-mounted remote control assembly 260 may be deployed in load control systems with more or fewer electrical loads and/or more or fewer associated load control devices. It should further be appreciated that the cord-mounted remote control assembly 260 is not limited to use in a load control system that uses the illustrated load control devices (e.g., the illustrated plug-in RF dimmer switch and wall-mounted RF dimmer switch). For example the cord-mounted remote control assembly 260 may be deployed in load control systems using one or more of the following example load control devices configured for control via wireless communication (e.g., via the remote control device 270): an electronic dimming ballast for a fluorescent lamp; a light-emitting diode (LED) driver for an LED light source; a dimmer circuit for types of lighting loads such as magnetic low-voltage lighting loads, electronic low voltage lighting loads, or screw-in compact fluorescent lamps; a controllable luminaire (e.g., that houses a load control device and an electrical load) that is adapted to be screwed into an electrical socket (e.g., the Edison socket of a lamp); a motorized window treatment (e.g., a roller shade, a drapery, or the like); a temperature control device (e.g., a thermostat); an audio/visual control device; or a switching device for an appliance or other electrical load.

It should be appreciated that the cord-mounted remote control assembly 260 is not limited to being mounted to the power cord of a component of the load control system in which it is deployed, for example the power cord 222 of the table lamp 220 as illustrated in FIG. 2. For example, the cord-mounted remote control assembly 260 may be mounted to the power cord of any other device or appliance within RF range of the load control devices that the remote control device 270 of the cord-mounted remote control assembly 260 is configured to control, for example an alarm clock, a radio, a video monitor, a coffee maker, a floor lamp, etc. Furthermore, it should be appreciated that the cord-mounted remote control assembly 260 is not limited to mounting exclusively on cords, such as standard electrical power cords. For example, the cord-mounted remote control assembly 260 may alternatively be mounted to other cord and/or rod-like structures, such as the pull chain of a lamp, the pipe of a lamp, the harp of a lamp, or the like.

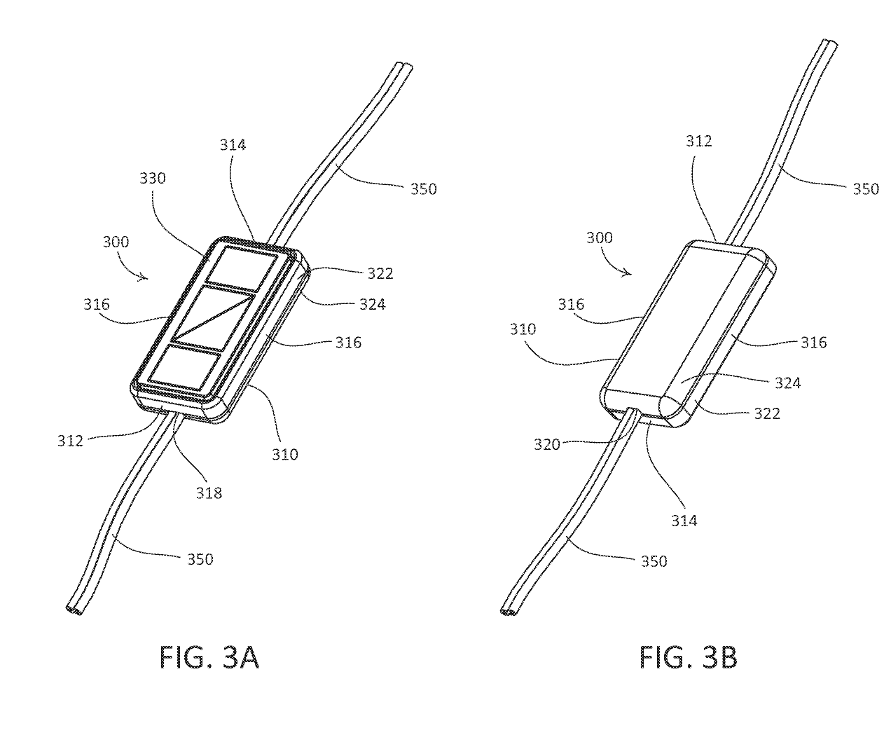

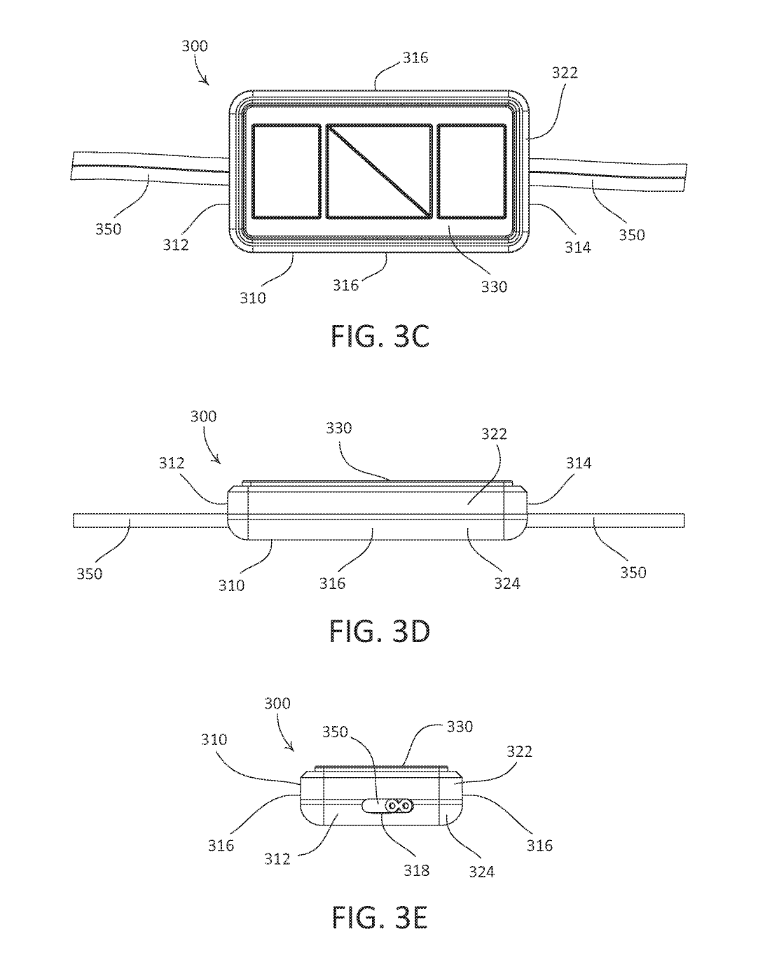

FIGS. 3A-3E depict an example cord-mounted remote control assembly 300 that is mounted to a portion of an electrical power cord 350. The cord-mounted remote control assembly 300 may be deployed, for example, as the cord-mounted remote control assembly 260 as depicted in FIG. 2. The cord-mounted remote control assembly 300 includes a housing 310 and a remote control device 330. The remote control device 330 may be deployed, for example, as the remote control device 270 of the cord-mounted remote control assembly 260. The remote control device 330 may be configured to be releasably attachable to the housing 310. Alternatively, the cord-mounted remote control assembly 300 may be configured such that the remote control device 330 is integrated with, for example partially or fully monolithic with respect to, the housing 310. The remote control device 330 may be configured to control one or more load control devices, for example using RF signals.

The housing 310 may define any suitable shape, such as the illustrated rectangular block shape. As shown, the housing 310 defines a first end 312, an opposed second end 314, and opposed sides 316. The housing 310 is elongate between the first and second ends 312, 314. Stated differently, the first end 312 is spaced from the second end 314 by a first distance, and the sides 316 are spaced apart by a second distance that is shorter than the first distance.

The housing 310 may be configured to be fixedly mounted to a portion of the power cord 350. For example, the housing 310 may define a path therethrough (not shown) that is configured to receive a portion of the power cord 350. The housing 310 may define the path such that the path is configured to restrain the cord in position within the housing 310. As shown, the first end 312 of the housing 310 defines a first opening 318 and the second end 314 of the housing defines a second opening 320. The first and second openings 318, 320 may be open to the path through the housing 310. As shown, the first and second openings 318, 320 define respective perimeter profiles that are configured to substantially conform to a cross-sectional, outer profile of the power cord 350. The electrical power cord 350 may be, for example, standard 18/2 lamp wire.

The housing 310 may include two or more pieces that may be configured to be attached to each other, such that the housing 310 may be mounted to the power cord 350 without cutting the power cord 350. As shown, the housing 310 is a two piece housing that includes a first piece 322 and a second piece 324. The first and second pieces 322, 324 of the housing 310 may be configured to be attached to each other (e.g., semi-permanently attached to each other), so as to enclose a portion of the power cord 350 in the housing 310. The first piece 322 may define a cradle portion of the housing 310 that is configured to receive at least a portion of the remote control device 330, for example in releasable attachment to the housing 310. Alternatively, the remote control device 330 may be integrated with the first piece 322 of housing 310. The second piece 324 may define a cover portion of the housing 310 that may be referred to as a back cover, or rear cover, of the housing 310.

The second piece 324 of the housing 310 may define a path through the housing 310 that is configured to receive and restrain a portion of the power cord 350. In an example assembled configuration of the cord-mounted remote control assembly 300, as shown in FIGS. 3A-3E, the first and second pieces 322, 324 of the housing 310 may be secured to each other and a portion of the power cord 350 may be disposed in the path through the housing 310. For example, the power cord may be disposed in the first and second openings 318, 320 and may follow the path through the housing 310, such that the power cord 350 protrudes from both the first and second ends 312, 314 of the housing 310. The housing 310, for example the first and/or second pieces 322, 324, may be made of any suitable material, such as plastic. The first and second pieces 322, 324 of the housing 310, respectively, may be made of the same or different materials.

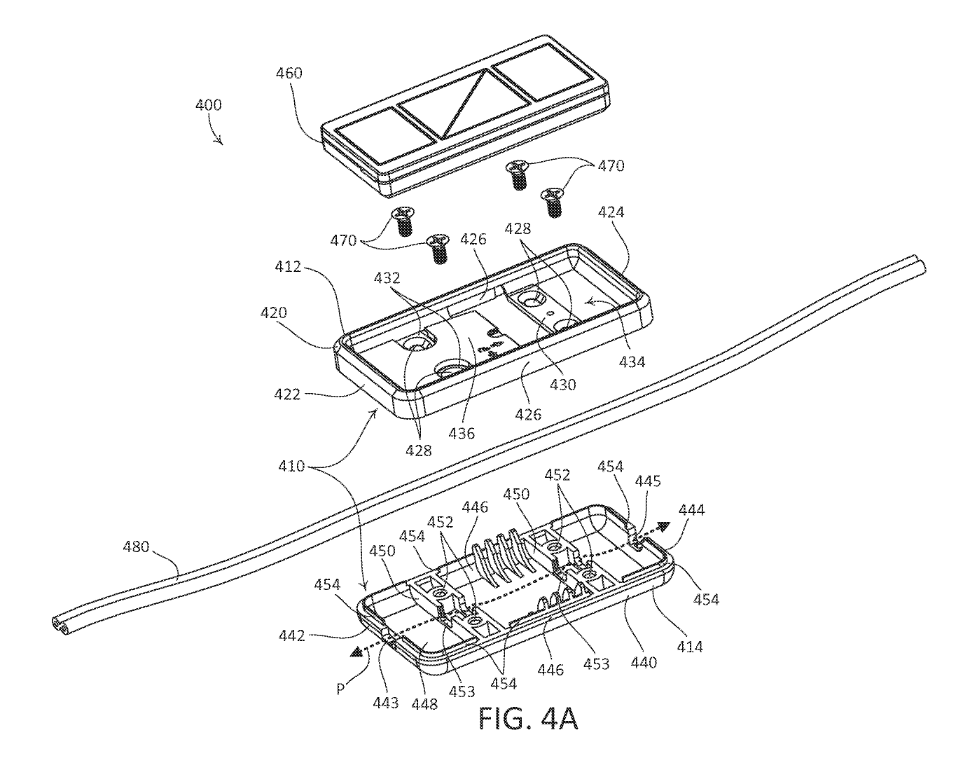

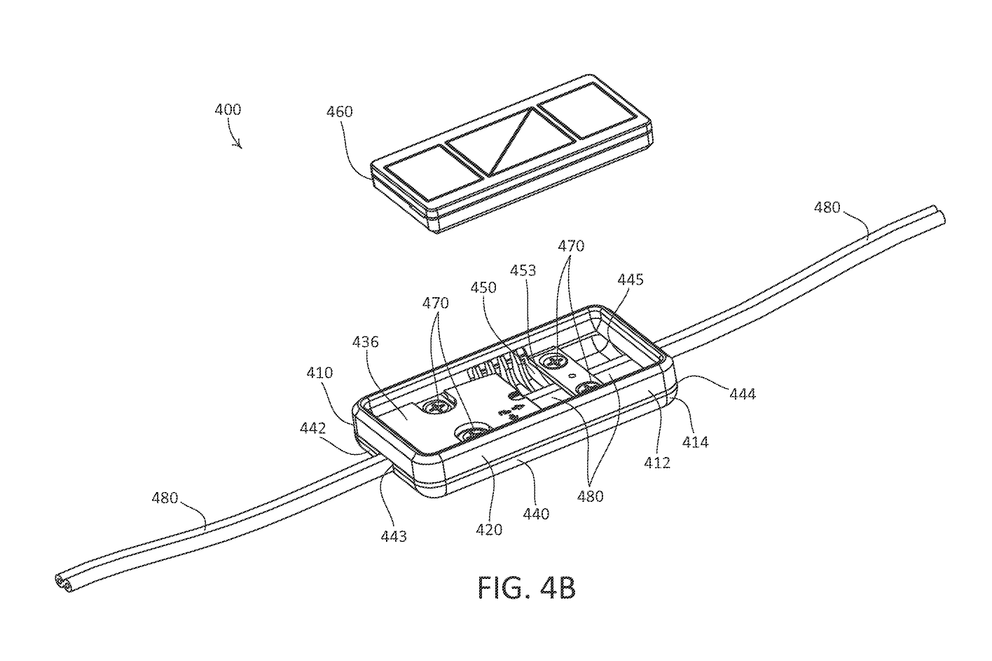

FIG. 4A is an exploded view depicting components of an example cord-mounted remote control assembly 400. Also depicted is a length of power cord 480, for example standard 18/2 lamp wire, that the cord-mounted remote control assembly 400 may be mounted to. The cord-mounted remote control assembly 400, when assembled, may be deployed as the cord-mounted remote control assembly 300 as depicted in FIGS. 3A-3E and/or as the cord-mounted remote control assembly 260 as depicted in FIG. 2, for example.

The components of the illustrated cord-mounted remote control assembly 400 include a two piece housing 410 and a remote control device 460. The remote control device 460 may be configured to be releasably attachable to the housing 410. In such a configuration, the housing 410 may be referred to as a mount for the remote control device 460. Alternatively, the cord-mounted remote control assembly 400 may be configured such that the remote control device 460 is integrated with, for example partially or fully monolithic with, the housing 410. The remote control device 460 may be configured to control one or more load control devices, for example using RF signals. The remote control device 460 may be deployed, for example, as the remote control device 330 of the cord-mounted remote control assembly 300 and/or as the remote control device 270 of the cord-mounted remote control assembly 260.

As shown, the housing 410 is a two piece housing that includes a first piece 412 and a second piece 414. The first and second pieces 412, 414 of the housing 410 may be configured to be attached to each other (e.g., semi-permanently attached to each other). As shown, the first and second pieces 412, 414 of the housing 410 are configured to be secured to one another using a plurality of fasteners, such as the illustrated screws 470. It should be appreciated that the securement of the first and second pieces 412, 414 to each other is not limited to the illustrated screws 470, and that one or both of the of the first and second pieces 412, 414 of the housing 410 may be alternatively configured to attach to each other. For example, one or both of the first and second pieces 412, 414 may define one or more snap fit connectors (not shown), and one or both of the first and second pieces 412, 414 may define corresponding complementary apertures (not shown) configured to receive the one or more snap fit connectors. The housing 410, for example the first and/or second pieces 412, 414, may be made of any suitable material, such as plastic. The first and second pieces 412, 414 of the housing 410, respectively, may be made of the same or different materials.

The first piece 412 may define a cradle portion 420 of the housing 410. As shown, the cradle portion 420 may include a first end wall 422, a second end wall 424 that is spaced from the first end wall 422, and a pair of side walls 426 that are spaced apart from each other and that extend from corresponding ends of the first end wall 422 to corresponding ends of the second end wall 424. As shown, the cradle portion 420 is elongate along a direction between the first and second end walls 422, 424. Stated differently, the first and second end walls 422, 424 define respective lengths that are shorter than respective lengths of the side walls 426.

The cradle portion 420 may define a plurality of apertures 428 that are configured to receive corresponding ones of the screws 470. As shown, the cradle portion 420 defines a cross member 430 that extends from side wall 426 to side wall 426, and defines two apertures 428 that extend therethrough. The illustrated cradle portion 420 further defines a pair of opposed tabs 432 that extend inwardly toward each other, one tab 432 from each of the side walls 426. Each tab 432 defines an aperture 428 that extends therethrough.

The cradle portion 420 of the housing 410 may be configured to receive at least a portion of the remote control device 460, for example in releasable attachment to the housing 410. As shown, the first end wall 422, the second end wall 424, and the side walls 426 define a cavity 434 that extends into the cradle portion 420. The illustrated cavity 434 is sized to receive at least a portion of the remote control device 460. The cradle portion 420 may be configured to retain the remote control device 460 in releasable attachment to the housing 410. For example, the cradle portion 420 may include an attachment component that is configured to enable releasable attachment of the remote control device 460 to the housing 410. For example, the illustrated cradle portion 420 defines a resilient deflectable, cantilevered paddle 436 that is supported by the first end wall 422 and extends into the cavity 434, and that is configured to be received in a complementary recess (not shown) defined by the remote control device 460 (e.g., by a housing of the remote control device 460), so as to captively engage the remote control device 460 in the cavity 434. The paddle 436 may be referred to as a retention member that is configured to releasably retain the remote control device 460 in the cavity 434. An example paddle that may be implemented as the paddle 436 is described in more detail in commonly-assigned U.S. Pat. No. 8,389,857, issued Mar. 5, 2013, entitled “Structure for Mounting a Wireless Battery-Powered Remote Control,” the entire disclosure of which is incorporated herein by reference.

One or both of the cradle portion 420 and the remote control device 460 may be configured such that the remote control device 460 may be fixedly retained in the cavity 434 (e.g., semi-permanently or permanently retained). To illustrate, the cross member 430 may be configured to attach to a corresponding portion of the remote control device 460 when the remote control device 460 is inserted into the cavity 434. For example, one or more adhesive components (e.g., a piece of double-sided adhesive tape) may be attached to one or both of the cross member 430 and a corresponding portion of the remote control device 460, prior to insertion of the remote control device 460 into the cavity 434. Alternatively, the cross member 430 and the remote control device 460 may define complementary mechanical fasteners, for example complementary snap fit connectors and apertures. It should be appreciated that point of attachment for securing the remote control device 460 to the cradle portion 420 are not limited to the paddle 436 and/or the cross member 430, and that the cradle portion 420 and/or the remote control device 460 may alternatively define one or more other attachment structures configured to secure the remote control device 460 to the cradle portion 420. Alternatively, the remote control device 460 may be integrated with, for example partially or fully monolithic with respect to, the cradle portion 420 of housing 410.

The second piece 414 may define a cover portion 440 of the housing 410. The cover portion 440 may be referred to as a back cover, or rear cover, of the housing 410. As shown, the cover portion 440 may include a first end wall 442, a second end wall 444 that is spaced from the first end wall 442, a pair of side walls 446, and a floor 448. The side walls 446 are spaced apart from each other, and extend from corresponding ends of the first end wall 442 to corresponding ends of the second end wall 444. The floor 448 extends from the first end wall 442 to the second end wall 444, and from side wall 446 to side wall 446. The first and second end walls 442, 444, the side walls 446, and the floor 448 define an interior volume of the cover portion 440 that may be at least partially hollow. The illustrated cover portion 440 defines a pair of cross members 450 that extend across the interior volume of the cover portion 440, from side wall 446 to side wall 446, and from the floor 448 to respective upper ends of the side walls 446. As shown, the cover portion 440 is elongate along a direction between the first and second ends walls 442, 444. Stated differently, the first and second end walls 442, 444 define respective lengths that are shorter than respective lengths of the side walls 446.

The cover portion 440 of the housing 410 may be configured to be attached to the cradle portion 420 (e.g., semi-permanently attached). For example, the cover portion 440 may define a plurality of apertures 452 that are configured to receive corresponding ones of the screws 470. As shown, the cover portion 440 defines two pairs of apertures 452, such that each pair of apertures 452 extends into a respective one of the cross members 450. The apertures 452 may be threaded or non-threaded in any combination. The pair of apertures 452 in a first one of the cross members 450 that is closer to the first end wall 442 than to the second end wall 444 may be configured to align with the apertures 428 that extend through the tabs 432 of the cradle portion 420, for example when the cradle portion 420 is aligned with the cover portion 440. The pair of apertures 452 in a second one of the cross members 450 that is closer to the second end wall 444 than to the first end wall 442 may be configured to align with the apertures 428 that extend through the cross member 430 of the cradle portion 420, for example when the cradle portion 420 is aligned with the cover portion 440.

One or both of the cradle portion 420 or the cover portion 440 may be configured to facilitate alignment of the pieces relative to each other, for example when attaching the cradle portion 420 and the cover portion 440 to each other. As shown, the cover portion 440 defines a plurality of alignment projections 454 that extend outwardly from respective upper ends of the first and second end walls 442, 444 and the side walls 446. When disposing the cradle portion 420 onto the cover portion 440, respective inner surfaces of the first end wall 422, the second end wall 424, and/or one or both side walls 426, may abut corresponding ones of the alignment projections 454, to facilitate alignment of the cradle portion 420 with the cover portion 440. This may facilitate alignment of the apertures 428 of the cradle portion 420 with corresponding ones of the apertures 452 of the cover portion 440, for example.

The cover portion 440 may be configured with an outer perimeter profile (e.g., as defined by respective outer surfaces of the first end wall 442, the second end wall 444, and the side walls 446) that is substantially the same as an outer perimeter profile of the cradle portion 420 (e.g., as defined by respective outer surfaces of the first end wall 422, the second end wall 424, and the side walls 426). As shown, the respective outer wall surfaces of the cradle portion 420 and the cover portion 440 may be configured so as to define a smooth seam between the cradle portion 420 and the cover portion 440. Accordingly, when the first and second pieces 412, 414 of the housing 410 are attached to each other, the housing 410 may define a smooth outer perimeter surface. One or more of the alignment projections 454 of the cover portion 440 may facilitate the alignment of the respective outer wall surfaces of the cradle portion 420 and the cover portion 440.

The housing 410 may be configured to be fixedly mounted to a portion of the power cord 480. For example, the housing 410 may define a path therethrough that is configured to receive a portion of the power cord 480. Such a path may be defined by one or both of the cradle portion 420 and the cover portion 440. As shown, the cover portion 440 defines a path that is configured to receive a portion of the power cord 480. The path extends into the first end wall 442, through the interior volume of the cover portion 440, and out through the second end wall 444.

The cover portion 440 defines a first groove-shaped opening 443 that extends through the first end wall 442 and defines a second groove-shaped opening 445 that extends through the second end wall 444. The illustrated first and second openings 443, 445 define respective perimeter profiles that are configured to substantially conform to a cross-sectional, outer profile of the power cord 480. The cross member 450 of the cover portion 440 may be configured to define respective portions of the path through the housing 410. As shown, each cross member 450 defines a groove 453 that is configured to receive a portion of the power cord 480. One or both of the grooves may be configured to substantially conform to a cross-sectional, outer profile of the power cord 480, and may be configured to constrain the power cord 480 from movement along the path. An example path P through the housing 410 that the power cord 480 may follow is illustrated by a broken line in FIG. 4A.

It should be appreciated that the housing 410 is not limited to the illustrated path therethrough, and that one or both of the cradle portion 420 and the cover portion 440 of the housing 410 may be alternatively configured to differently define a path through the housing. For example, the housing 410 (e.g., the cover portion 440) may be configured to define a path that extends through the housing from side wall 446 to side wall 446, rather than through the first and second end walls 442, 444. In another example the housing 410 (e.g., the cover portion 440) may be configured to define a path that extends through the housing 410 and includes a ninety degree bend in the power cord 480. To implement such example configurations, the cover portion 440 may define one or both of the first and second openings 443, 445, and may additionally define respective openings in one or both of the side walls 446. In such a configuration, the housing 410 may define multiple paths for receiving the power cord 480. A cord-mounted remote control assembly with such a housing may further include one or more plugs that are configured to fill one or more unused openings in the housing 410.

In an example process of mounting the illustrated cord-mounted remote control assembly 400 to the power cord 480, a desired mounting location along the length of the power cord 480 may be selected. A portion of the power cord 480 that corresponds to the desired mounting location may be disposed into the path through the housing 410 (e.g., the path P). This may involve pressing corresponding portions of the power cord 480 into the first and second openings 443, 445 respectively, and into the grooves 453 of both cross members 450.

With the power cord 480 in place within the path through the housing 410, the cradle portion 420 may be disposed onto the cover portion 440 and secured thereto, for example as illustrated in FIG. 4B. This may involve aligning the cradle portion 420 with the cover portion 440, for example with the aid of one or more of the plurality of alignment projections 454. With the cradle and cover portions 420, 440 aligned with respect to each other, the screws 470 may be inserted into respective ones of the apertures 428, and driven into position in the apertures 452. As the screws 470 are tightened, the tabs 432 may be brought into contact with the first cross member 450 of the cover portion 440 and the cross member 430 of the cradle portion 420 may be brought into contact with the second cross member 450 of the cover portion 440. Abutment of the tabs 432 and the cross member 430 with the first and second cross members 450 may define a width of the seam between the cradle and cover portions 420, 440. With the housing 410 mounted to the power cord 480, the remote control device 460 may be attached to the housing 410.

It should be appreciated that the housing 410 of the cord-mounted remote control assembly 400 is not limited to the illustrated two piece configuration, and that the housing 410 may be alternatively configured to mount to the power cord 480. For example, the first and second pieces 412, 414 of the housing 410 may be attached to one another by a hinged structure, such that once the power cord 480 is disposed into the housing 410, the first and second pieces 412, 414 may be rotated toward each other about the hinged structure, and secured to each other. To illustrate, a side wall 426 of the cradle portion 420 may be hingedly attached to a corresponding side wall 446 of the cover portion 440, such that when the power cord 480 is disposed into the path through the cover portion 440, the cradle portion 420 may be closed (e.g., by rotating the cradle portion 420 relative to the cover portion 440 about the hinged structure) and secured to the cover portion 440, thereby securely mounting the housing 410 to the power cord 480.

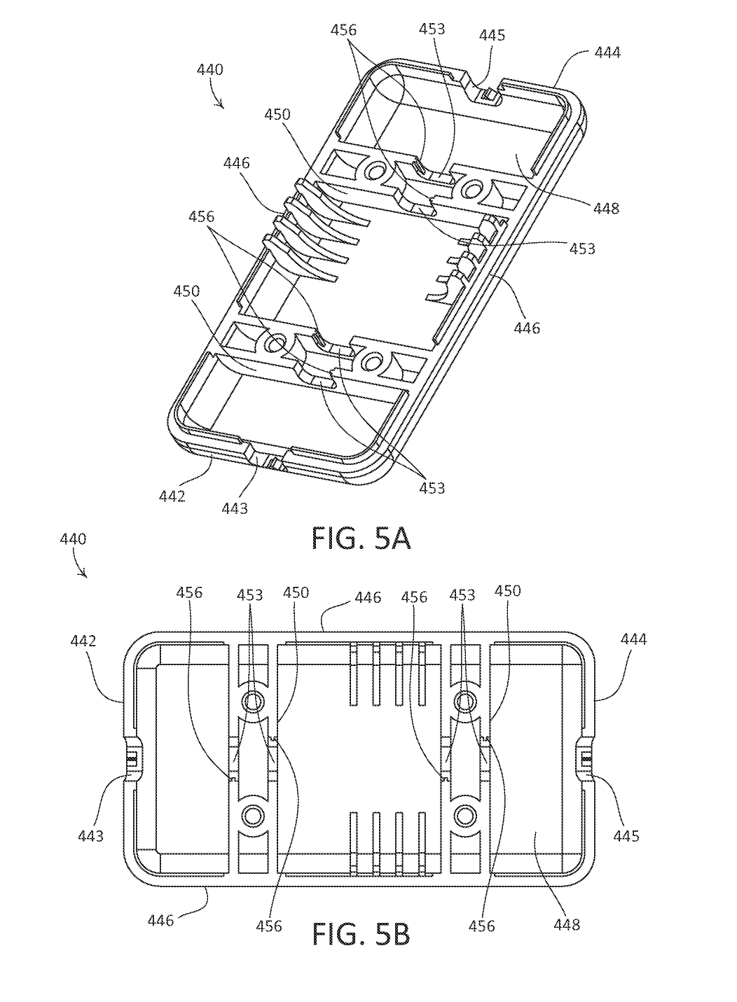

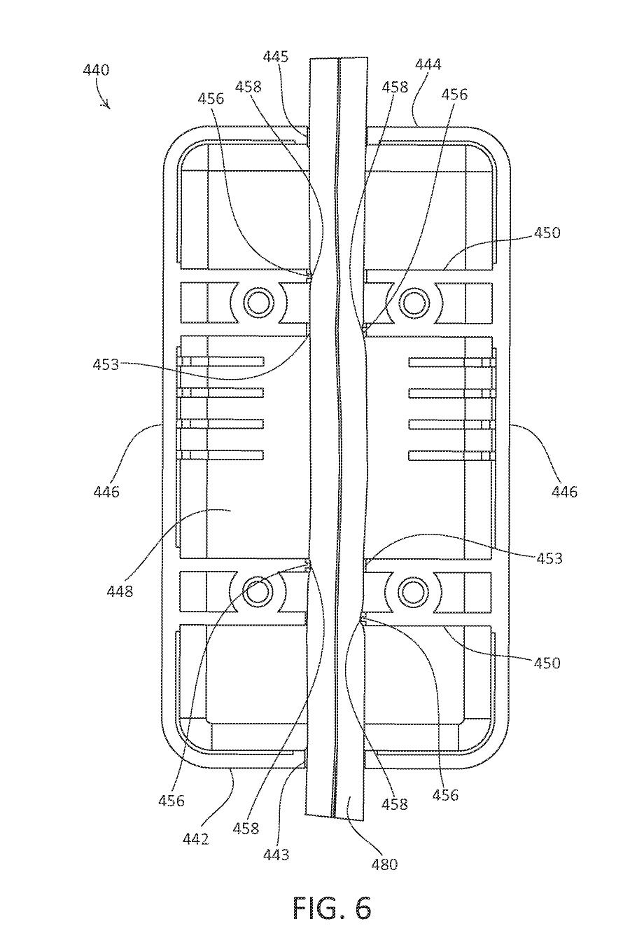

Referring additionally to FIGS. 5A, 5B, and 6, the housing 410 may be configured to be fixedly mounted to the power cord 480, such that the cord-mounted remote control assembly 400 remains in a desired mounting location on the power cord 480. The cover portion 440 of the housing 410 may define the path through the housing 410 such that movement of the housing 410 relative to the power cord 480, for example along the power cord 480, is restrained. For example, the housing 410 may be configured to engage an outer surface of the power cord 480 (e.g., the insulating sheath of the power cord 480) in at least one location between the first and second openings 443, 445, for example in at least one location along the path through the housing 410.

The housing 410 may include one or more gripping components that are configured to engage the insulating sheath of the power cord 480. For example, the housing defines a plurality of engagement ribs 456 that are spaced apart from each other in the housing 410, between the first and second end walls 442, 444. The plurality of engagement ribs 456 may be defined, for example, by the cross members 450. As shown, each cross member 450 defines a pair of engagement ribs 456 that extend into the groove 453 of the cross member 450 from opposed sides of the groove 453. The engagement ribs 456 of each cross member may be spaced apart from each other along a direction between the first and second end walls 442, 444. As shown, the engagement ribs 456 of each cross member 450 are spaced apart from each other in a staggered fashion, such that a first engagement rib 456 of each pair is located closer to the first end wall 442 (e.g., to the first opening 443) of the cover portion 440 than is a second engagement rib 456 of each pair. Stated differently, a second engagement rib 456 of each pair may be spaced further from the first opening 443 than a first engagement rib 456 of each pair is spaced from the first opening 443.

The engagement ribs 456 may protrude into the respective grooves 453 defined by the cross members 450 such that when the power cord 480 is disposed in the path through the housing 410, the engagement ribs 456 make contact with, but do not penetrate, the insulating sheath of the power cord 480 at one or more contact locations 458 along the power cord 480. When the power cord 480 is disposed in the groove 453, a first engagement rib 456 of each pair may contact (e.g., bias) a first side of the insulating sheath of the power cord 480 and a second engagement rib 456 each pair may contact (e.g., bias) a second, opposed side of the insulating sheath of the power cord 480. When the engagement ribs 456 are in contact with the insulating sheath of the power cord 480, movement of the engagement ribs 456, and thus of the housing 410, relative to the power cord 480 may be restrained.

When a first force (e.g., a tensile force) is applied to the power cord 480, and a second force that opposes the first force is applied to the cord-mounted remote control assembly 400 (e.g., to the housing 410), the engagement ribs 456 may grip the insulating sheath of the power cord 480, such that the power cord 480 does not move relative to the engagement ribs 456. The engagement ribs 456 may be configured to restrain the cord-mounted remote control assembly in position relative to the power cord 480, until one or both forces exceed respective predetermined thresholds, at which point the cord-mounted remote control assembly 400 (e.g., the housing 410) may move relative to the power cord 480 (e.g., slide along the power cord 480). Once such forces are no longer applied, or when such forces no longer exceed the respective predetermined thresholds, the housing 410 may once again restrain movement of the cord-mounted remote control assembly 400 relative to the power cord 480. It should be appreciated that the housing 410 is not limited to the illustrated number and or configuration of engagement ribs 456, and that the cover portion 440 of the housing 410, for example, may be alternatively constructed with more or fewer engagement ribs, in any suitable locations along the path through the housing 410.

It should be appreciated that cord-mounted remote control assemblies, for example the cord-mounted remote control assemblies 260, 300, 400 illustrated and described herein, are not limited to configurations for mounting to standard 18/2 lamp wire. For example, the corresponding housings of any of the cord-mounted remote control assemblies described herein may be alternatively configured to be mountable to and/or to restrain corresponding portions of other types of electrical cords, for example, U.S. domestic power cords, international power cords, cords of different voltage ratings, cords of different current ratings, and so on. Furthermore, the cord-mounted remote control assemblies described herein are not limited to mounting on electrical cords. For example, the corresponding housings of the cord-mounted remote control assemblies described herein may be alternatively configured to be mountable to other cord and/or rod-like structures, such as the pull chain of a lamp, the pipe of a lamp, the harp of a lamp, or the like.

It should further be appreciated that cord-mounted remote control assemblies, for example the cord-mounted remote control assemblies 260, 300, 400 illustrated and described herein, are not limited to the illustrated remote control devices 270, 330, and 460, respectively. For example, each of the remote control devices 270, 330, and 460 have a similar layout that includes four smooth-faced, physical buttons that may be actuated to transmit RF command signals to one or more associated load control devices. However, one or more of the remote control devices 270, 330, and 460 may be alternatively configured with button configurations that are different than those illustrated (e.g., with more or fewer buttons). For example, one or more of the remote control devices 270, 330, and 460 may be configured in accordance with the example RF remote control device button layouts described in more detail in commonly-assigned U.S. Patent Application Publication No. 2012/0286940, published Nov. 15, 2012, entitled “Control Device Having a Nightlight,” the entire disclosure of which is incorporated herein by reference.

It should further still be appreciated that the remote control devices 270, 330, and 460 are not limited to the illustrated smooth-faced buttons. For example, one or buttons of one or more of the remote control devices 270, 330, and 460 may be alternatively configured to include a tactile indicator on its face. Such a tactile indicator may be indicative of respective load control device functions that correspond to command signals that are transmitted when the one or more buttons are actuated. If the remote control device (e.g., remote control device 270, 330, or 460) of a cord-mounted remote control assembly is configured with one or more such tactile indicators, an orientation in which the cord-mounted remote control assembly is mounted to a power cord may be less important than if the buttons of the remote control device were all similarly smooth-faced. An example of a tactile indicator is described in more detail in commonly-assigned U.S. Patent Application Publication No. 2013/0229269, published Sep. 5, 2013, entitled “Remote Control Having Indicia and a Locator Bump,” the entire disclosure of which is incorporated herein by reference.

It should further still be appreciated that the remote control device of a cord-mounted remote control assembly, for example the remote control devices 270, 330, and 460 of the cord-mounted remote control assemblies 260, 300, 400, respectively, as illustrated and described herein, is not limited to actuators that are buttons. For example, the remote control device of a cord-mounted remote control assembly may include one or more other types of actuators (e.g., in addition to or in lieu of one or more buttons), such as rotating knobs, sliders, touch-sensitive actuators, or the like.

The remote control device of a cord-mounted remote control assembly, for example the remote control devices 270, 330, and 460 of the cord-mounted remote control assemblies 260, 300, 400, respectively, as illustrated and described herein, may be battery powered. The remote control device of a cord-mounted remote control assembly may include circuitry configured to inductively charge the battery of the remote control device, for example using current that passes through the power cord to which the cord-mounted remote control assembly is mounted. Alternatively, the housing of the cord-mounted remote control assembly may be configured to pierce the insulating sheath of the power cord to which the cord-mounted remote control assembly is mounted at one or more locations, such that a small current may be drawn from the power cord and used to power the remote control device and/or to charge the battery of the remote control device. For example, the housing of such a cord-mounted remote control assembly may include a structure (e.g., similar to an engagement rib 456) that is electrically conductive, that is configured to pierce the insulating sheath of the power cord, and is electrically connected to the circuitry of the remote control device.

1. A remote control assembly configured to mount to a power cord, the remote control assembly comprising:
a housing that defines a path therethrough that is configured to receive a portion of the cord and to restrain the cord within the housing; and
a remote control device that is configured to control a load control device via wireless signals transmitted from the remote control device,
wherein the remote control device is releasably attachable to the housing.

2. The remote control assembly of claim 1, wherein the housing is elongate between a first end that defines a first opening and an opposed second end that defines a second opening, the path through the housing open to the first and second openings.

3. The remote control assembly of claim 2, wherein the housing is configured to engage an outer surface of the power cord in at least one location between the first and second openings.

4. The remote control assembly of claim 2, wherein the housing defines a first engagement rib that biases a first side of the power cord and a second engagement rib that biases an opposed second side of the power cord.

5. The remote control assembly of claim 4, wherein the first and second engagement ribs are spaced apart from each other such that the second engagement rib is spaced further from the first opening than the first engagement rib is spaced from the first opening.

6. The remote control assembly of claim 5, wherein the housing includes a cover that defines the first and second engagement ribs and a cradle that is configured to attach to the cover and to releasably attach to the remote control device.

7. A mount for a remote control device, the mount comprising:
a gripping component that is configured to engage a portion of an electrical cord, the gripping component configured to contact an insulating sheath of the electrical cord at a plurality of locations, such that movement of the gripping component relative to the electrical cord is restrained; and
an attachment component that is configured to enable releasable attachment of the remote control device to the remote control mount.

8. The mount of claim 7, wherein movement of the gripping component relative to the electrical cord is restrained until a predetermined strain threshold is exceeded.

9. The mount of claim 8, wherein the gripping component includes first and second pairs of engagement ribs.

10. The mount of claim 9, wherein a first engagement rib of each pair contacts the insulating sheath at a first location along the electrical cord and a second engagement rib of each pair contacts the insulating sheath at a second location along the electrical cord that is spaced from the first location.

11. The mount of claim 10, wherein the first location and second locations are on opposed sides of the electrical cord.

12. The mount of claim 7, wherein the attachment component comprises a cantilevered paddle that is configured to be received in a recess defined by a housing of the remote control device.

13. The mount of claim 7, wherein the housing further comprises a cover that defines the gripping component and a cradle that supports the attachment component, the cover and the cradle configured to be attached to each other so as to enclose a portion of the electrical cord.

14. A housing configured to releasably retain a remote control device, the housing comprising:
a first piece that includes a retention member that is configured to retain the remote control device; and
a second piece that is configured to engage with a complementary structure of an object to which the housing is mounted, wherein engagement of the second piece with the complementary structure fixes the housing in a position relative to the object,
wherein the first piece is configured to be attached to the second piece.

15. The housing of claim 14, wherein the first piece defines a cradle that is configured to enclose a portion of the remote control device when the remote control device is releasably attached to the housing.

16. The housing of claim 14, wherein the retention member includes a resiliently deflectable paddle that is cantilevered with respect to the first piece and that is configured to be received in a corresponding recess defined by the remote control device.

17. The housing of claim 14, wherein the second piece is monolithic.

18. The housing of claim 14, wherein the second piece defines a path that extends therethrough and that is configured to receive a portion of the complementary structure therein.

19. The housing of claim 18, wherein the second piece defines a plurality of projections that extend into the path so as to engage with the complementary structure when the complementary structure is disposed in the path.

20. The housing of claim 19, wherein the plurality of projections comprise a plurality of engagement ribs that are configured to engage with, but not penetrate, an insulating sheath of a power cord.

21. A load control system comprising:
a load control device that is configured to control an amount of power delivered from an alternating current (AC) power source to an electrical load;
a housing that is mounted to an electrical power cord; and
a remote control device mounted to the housing, the remote control device configured to control the load control device by transmitting radio frequency control signals to the load control device.

22. The load control system of claim 21, further comprising an electrical load that is electrically connected to the load control device, wherein the load control device is plugged into an AC power receptacle and the electrical load is plugged into the load control device.

23. The load control system of claim 21, further comprising an electrical load that is electrically connected to the load control device, wherein the load control device and the electrical load are housed in a controllable luminaire, the controllable luminaire that is configured to be screwed into an Edison socket.

24. The load control system of claim 21, wherein the housing is configured to allow releasable attachment of the remote control device to the housing.
